(19) United States
(12) Patent Application Publication
(10) Pub. No.: US 2025/0062152 A1
(43) Pub. Date: Feb. 20, 2025

(54) DICING FILM AND METHOD OF MANUFACTURING SEMICONDUCTOR PACKAGE BY USING THE SAME

(71) Applicant: Samsung Electronics Co., Ltd., Suwon-si (KR)

(72) Inventors: Hyungjun Kim, Suwon-si (KR); Cheol-Hee Ahn, Seoul (KR); Yooseon Hong, Seoul (KR)

(73) Assignees: Samsung Electronics Co., Ltd., Suwon-si (KR); Seoul National University R&DB Foundation, Seoul (KR)

(21) Appl. No.: 18/804,824

(22) Filed: Aug. 14, 2024

(30) Foreign Application Priority Data
Aug. 16, 2023 (KR) 10-2023-0107096

(51) Int. Cl. H01L 21/683; C09J 4/00; C09J 7/38; H01L 23/00

(52) U.S. Cl. CPC H01L 21/6836; C09J 4/00; C09J 7/385; H01L 24/97; H01L 2224/95001

(57) ABSTRACT

In a dicing film, an adhesive strength of an adhesive layer constituting the dicing film may sufficiently decrease after heat treatment, and a semiconductor die may be easily separated from the dicing film. Accordingly, the effect of improving pickup performance of the semiconductor die may be obtained.

### CROSS-REFERENCE TO RELATED APPLICATION

This application is based on and claims priority under 35 U.S.C. § 119 to Korean Patent Application No. 10-2023-0107096, filed on Aug. 16, 2023, in the Korean Intellectual Property Office, the disclosure of which is incorporated by reference herein in its entirety.

### BACKGROUND

The inventive concept relates to a dicing film and a method of manufacturing a semiconductor package by using the same.

Recently, the demand for portable devices has rapidly increased in the electronic product market. Therefore, there is a continuous need for miniaturization and weight reduction of electronic components mounted on these products, for example, semiconductor chips. To achieve miniaturization and weight reduction of electronic components, semiconductor packages mounted thereon are required to process high-capacity data while having a small volume. Thus, there is a need for high integration and single packaging of semiconductor chips mounted on semiconductor packages. To satisfy such requirements, a substrate structure is diced to form a plurality of semiconductor dies, and each of the semiconductor dies may be manufactured into a semiconductor package. Therefore, there is a need for a dicing film with excellent pickup performance for manufacturing a semiconductor die after a process of dicing a substrate structure.

### SUMMARY

Aspects of the inventive concept provide a dicing film, and more particularly a dicing film including a high-temperature curable adhesive and a method of manufacturing a semiconductor package by using the same. The adhesive strength of an adhesive layer constituting the dicing film may sufficiently decrease after a heat treatment is performed thereon, and a semiconductor die may be easily separated from the dicing film, and thus, a pickup performance of the semiconductor die may be improved.

The inventive concept provides a method of manufacturing a semiconductor package, in which an adhesive strength of an adhesive layer constituting the dicing film may sufficiently decrease after heat treatment is performed thereon, and a semiconductor die may be easily separated from the dicing film, and thus, a pickup performance of the semiconductor die may be improved.

The objectives of the inventive concept are not limited to those described above, and other objectives that are not mentioned herein will be clearly understood from the following description by those of ordinary skill in the art.

According to an aspect of the inventive concept, there is provided a dicing film including a base layer, an intermediate layer on the base layer, and an adhesive layer on the intermediate layer, wherein the adhesive layer includes an acrylate polymer composition including acrylonitrile.

According to another aspect of the inventive concept, there is provided a pressure sensitive adhesive including an acrylate polymer composition including acrylonitrile in a range of 3 wt % to 50 wt %, wherein an adhesive strength of the pressure sensitive adhesive increases after an ultraviolet treatment is performed thereon, and the adhesive strength of the pressure sensitive adhesive decreases after a heat treatment is performed thereon.

According to another aspect of the inventive concept, there is provided a method of manufacturing a semiconductor package, the method including preparing a substrate structure with a first surface bonded on a carrier substrate, bonding, to a dicing film, a second surface of the substrate structure opposite to the first surface, separating the carrier substrate from the substrate structure and performing an ultraviolet treatment thereon, bonding a solder ball to the first surface of the substrate structure and performing a heat treatment thereon, separating the substrate structure into a plurality of semiconductor dies by cutting the substrate structure along a dicing line, debonding and picking up the semiconductor dies from the dicing film, and forming the semiconductor dies into semiconductor packages, respectively, wherein the dicing film includes a base layer, an intermediate layer on the base layer, and an adhesive layer on the intermediate layer, and wherein the adhesive layer includes an acrylate polymer composition including acrylonitrile.

A method of manufacturing a semiconductor package, according to the inventive concept, includes preparing a semiconductor wafer, bonding a dicing film to the semiconductor wafer, performing an ultraviolet treatment on the dicing film, performing a heat treatment on the dicing film, and debonding the semiconductor wafer from the dicing film, wherein the dicing film includes a base layer, an intermediate layer on the base layer, and an adhesive layer on the intermediate layer, and wherein the adhesive layer includes an acrylate polymer composition including acrylonitrile.

### BRIEF DESCRIPTION OF THE DRAWINGS

Embodiments will be more clearly understood from the following detailed description taken in conjunction with the accompanying drawings in which:

FIG. 1 is a schematic cross-sectional view illustrating a dicing film according to an embodiment;

FIG. 2 is a diagram illustrating a change in a formula according to a heat treatment for an adhesive layer of the dicing film of FIG. 1;

FIG. 3 is a graph showing experimental examples according to a heat treatment for the adhesive layer of the dicing film of FIG. 1;

FIG. 4 is a graph showing a change in an adhesive strength when acrylonitrile is not added to the adhesive layer of the dicing film;

FIG. 5 is a graph showing a change in an adhesive strength when acrylonitrile is added to the adhesive layer of the dicing film;

FIG. 6 is a flowchart of a method of manufacturing a semiconductor package, according to an embodiment;

FIGS. 7 to 16 are cross-sectional views illustrating a method of manufacturing a semiconductor packages, according to an embodiment; and

FIGS. 17 to 19 are diagrams illustrating other semiconductor packages manufactured by the method of manufacturing a semiconductor package, according to the inventive concept.

### DETAILED DESCRIPTION OF THE EMBODIMENTS

Embodiments will be described in detail with reference to the accompanying drawings in which various embodiments are shown. The invention may, however, be embodied in many different forms and should not be construed as limited to the example embodiments set forth herein. It should be emphasized that the disclosure provides details of alternative examples, but such listing of alternatives is not exhaustive. Furthermore, any consistency of detail between various examples should not be interpreted as requiring such. The language of the claims should be referenced in determining the requirements of the invention.

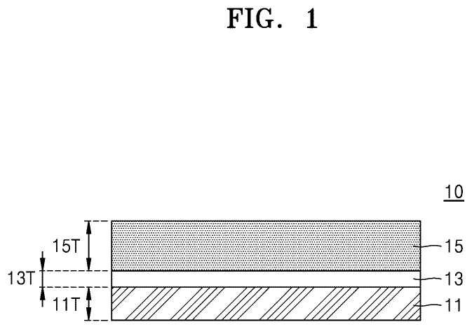

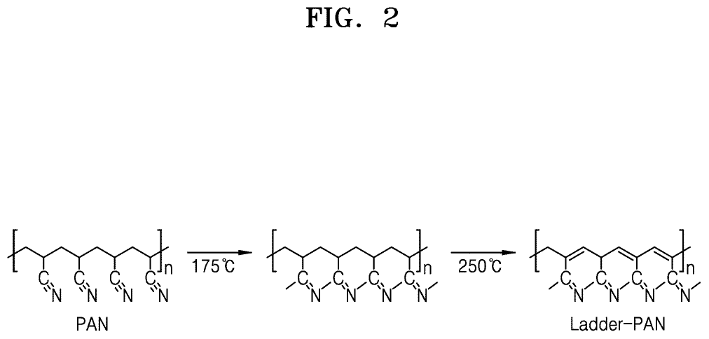

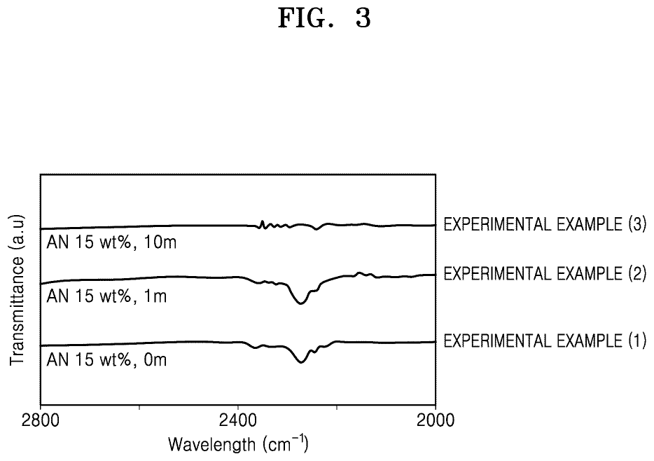

FIG. 1 is a schematic cross-sectional view illustrating a dicing film 10 according to an embodiment, FIG. 2 is a diagram illustrating a change in a formula according to a heat treatment for an adhesive layer 15 of the dicing film 10 of FIG. 1, and FIG. 3 is a graph showing experimental examples according to a heat treatment for the adhesive layer 15 of the dicing film 10 of FIG. 1.

Referring to FIGS. 1 to 3, the dicing film 10 may include a base layer 11, an intermediate layer 13 on the base layer 11, and the adhesive layer 15 on the intermediate layer 13. The dicing film 10 may also be referred to as a dicing support film or a substrate support film.

The dicing film 10 may have a circular shape having a first diameter. The first diameter may be greater than a second diameter of a substrate structure (e.g., the dicing film 10 may have a larger surface area than that of a substrate structure to which the dicing film 10 is applied). The second diameter is a diameter of a wafer constituting the substrate structure and may be, for example, about 300 millimeters (12 inches) or about 450 millimeters (18 inches).

The terms “adhesion” and “adhesive” as used herein may be lexically different from each other in a strict sense, but the term “adhesive” as used herein may be used as a comprehensive term that includes both adhesion and adhesive. In addition, the term “bonding” as used herein may be used as a term that includes both adhesion and adhesive. Elements constituting the dicing film 10 are described in more detail.

The base layer 11 may be referred to as a base film. The base layer 11 may be formed of and/or include a synthetic resin having a certain elastic modulus. The certain elastic modulus may be a certain Young's modulus. For example, the Young's modulus may be between 2 and 4 Gigapascals. The base layer 11 may be formed of and/or include, for example, a material selected from polyethylene terephthalate (PET), polyethylene naphthalate (PEN), polyether ether ketone (PEEK), and polyimide (PI). The base layer 11 may have a first thickness 11T. In some embodiments, the first thickness 11T may be about 20 micrometers to about 30 micrometers. The base layer 11 may increase the physical reliability of the dicing film 10 by physically supporting the adhesive layer 15 in the process of processing the substrate structure. In addition, the base layer 11 may increase the chemical reliability of the dicing film 10 by preventing moisture absorption (moisture penetration or moisture inhalation) that may occur in the process of processing the substrate structure.

The intermediate layer 13 may be disposed on the base layer 11. The intermediate layer 13 may be referred to as an anchor film. When the substrate structure to which a carrier substrate is bonded is mounted on the dicing film 10, the intermediate layer 13 may physically act as a buffer. The intermediate layer 13 may have a second thickness 13T. In some embodiments, the second thickness 13T may be about 1 micrometer to about 10 micrometers. The second thickness 13T of the intermediate layer 13 may be less than the first thickness 11T of the base layer 11. The intermediate layer 13 may be formed from and/or include, for example, a curable synthetic resin, which may be an ultraviolet (UV) curable synthetic resin or a non-UV curable synthetic resin. In some embodiments, the intermediate layer 13 may be formed of and/or include acrylate polymer and a crosslinking agent.

In the following description, the amount of a material may be indicated as a percentage by weight (wt %). The percentage by weight refers to the mass of the material divided by the total mass of the component being described. For example, the weight percentage of a particular material in a particular layer is given by the mass of the particular material in the particular layer divided by the total mass of the particular layer. Or, in another example, the weight percentage of a particular material in a particular composition is given by the mass of the particular material in a unit quantity of the particular composition divided by the total mass of the unit quantity of the particular composition.

A monomer composition constituting the acrylate polymer may include a first monomer, such as 2-ethylhexyl acrylate, 2-hydroxyethyl acrylate, or butyl acrylate, and the amount of the first monomer included in the acrylate polymer may be in a range of about 50 wt % to about 90 wt %. The acrylate polymer may include a second monomer, such as methacrylate, vinyl acetate, or styrene, as a cohesive component. The amount of the second monomer may be in a range of about 10 wt % to about 40 wt %. In addition, the acrylate polymer may include a third monomer, such as acrylic acid or methyl methacrylic acid. The third monomer may be included as a functional component and the amount of the third monomer may be in a range of about 2 wt % to about 20 wt %. However, the monomer compositions constituting the acrylate polymer are not limited thereto. In the acrylate polymer, the total amount of the monomer composition may be 100 wt % or less.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The crosslinking agent is not particularly limited as long as the crosslinking agent includes isocyanate. For example, the crosslinking agent may be at least one agent selected from the group consisting of an alicyclic compound, such as isophorone diisocyanate or methylenebiscyclohexane diisocyanate, an aliphatic compound, such as hexamethylene diisocyanate, and an aromatic compound, such as toluene diisocyanate, methylenediphenyl diisocyanate, or m-tetramethylxylylene diisocyanate, but the inventive concept is not limited thereto.

The adhesive layer 15 may be disposed on the intermediate layer 13. The adhesive layer 15 may be referred to as an adhesive film. In addition, the adhesive layer 15 may be a single layer. When the substrate structure to which the carrier substrate is bonded is mounted on the dicing film 10, the adhesive layer 15 may act as an adhesive. The adhesive layer 15 may have a third thickness 15T. In some embodiments, the third thickness 15T may be about 30 micrometers to about 40 micrometers. The third thickness 15T of the adhesive layer 15 may be greater than the first thickness 11T of the base layer 11. The adhesive layer 15 may be formed of and/or include, for example, a high-temperature curable, high-heat-resistant pressure sensitive adhesive (PSA). In some embodiments, the adhesive layer 15 may be formed of and/or include acrylate polymer, a crosslinking agent, and a photoinitiator. The acrylate polymer and the crosslinking agent constituting the adhesive layer 15 may be the same as, substantially the same as, or similar to those described above. Although the acrylate polymer and the crosslinking agent constituting the adhesive layer 15 may be the same as, substantially the same as, or similar to those described above, the acrylate polymer and the crosslinking agent constituting the adhesive layer 15 are not necessarily the same as the acrylate polymer and the crosslinking agent constituting the intermediate layer 13 in embodiments of the dicing film 10.

The photoinitiator may be, for example, at least one material selected from the group consisting of a benzoin compound, an acetophenone compound, an acylphosphine oxide compound, a titanocene compound, a thioxanthone compound, amine, and quinone. In some embodiments, the photoinitiator may be one of 1-hydroxycyclohexyl phenyl ketone, benzoin, benzoin methyl ether, benzoin ethyl ether, benzoin isopropyl ether, benzyl diphenyl sulfide, tetramethylthiuram monosulfide, azobisisobutyronitrile, dibenzyl, diacetyl, and beta-chloroanthraquinone, but the inventive concept is not limited thereto.

In the dicing film 10 according to the inventive concept, acrylonitrile may be included in the acrylate polymer, which is the main component of the adhesive layer 15. In some embodiments, the adhesive layer 15 may include acrylonitrile in a range of about 3 wt % to about 50 wt %. The inventors found that, when the adhesive layer 15 included less than about 3 wt % of acrylonitrile, the high-temperature curing effect was not sufficiently achieved. In addition, the inventors found that, when the adhesive layer 15 included more than about 50 wt % of acrylonitrile, a sufficient adhesive strength to bond the substrate structure was not secured.

The inventors found that, by including the acrylonitrile in the adhesive layer 15, an adhesive strength of the adhesive layer 15 increased after a UV treatment was performed thereon and decreased after a heat treatment was performed thereon.

The UV treatment may lead to the curing of the acrylate polymer in the adhesive layer 15 by the photoinitiator. That is, a polymerization reaction of the acrylate polymer may include a radical polymerization reaction using the photoinitiator. However, it is determined that the temperature of the substrate structure rises to about 150° C. due to the high quantity of light-emitting diode (LED) UV irradiation used in the process of manufacturing the semiconductor package, and thus, the adhesive strength increases.

In addition, the following chemical changes occur in the acrylonitrile in the adhesive layer 15 during a heat treatment at a certain temperature. Although not bound by a specific theory, it is determined that such chemical changes cause additional curing that further improves cohesion of a random copolymer, and thus, the adhesive strength decreases. Specifically, in a heat treatment at a certain temperature, the acrylonitrile undergoes a crosslinking reaction from Formula (1) below to Formula (2) below.

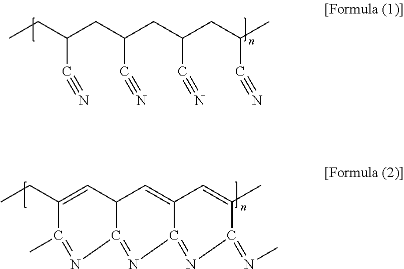

As illustrated in FIG. 2, Formula (1) goes through an intermediate change at about 175° C. and changes to Formula (2) at about 250° C. In other words, the acrylonitrile forms ladder-polyacrylonitrile (ladder-PAN) from polyacrylonitrile (PAN) in a heat treatment in a temperature range of about 175° C. to about 250° C., causing additional curing that further improves cohesion of the random copolymer. Accordingly, it may be seen that the adhesive strength decreases due to high-temperature curing.

As illustrated in FIG. 3, the inventors prepared adhesive samples including 15 wt % of acrylonitrile and experimented with different heat treatment times. Specifically, the presence of a triple bond between carbon (C) and nitrogen (N) was analyzed by measuring the transmittance of different wavelengths of light in the samples. In Experimental Example (1) a heat treatment was not performed, in Experimental Example (2) a heat treatment was performed for about 1 minute under process conditions of about 250° C., and in Experimental Example (3) a heat treatment was performed for about 10 minutes under process conditions of about 250° C.

First, it may be seen that, in Experimental Examples (1) and (2), the wavelength corresponding to the triple bond of carbon (C) and nitrogen (N) experienced reduced transmittance indicating the presence of the triple bond. This result may indicate that acrylonitrile maintains the form (PAN) shown in Formula (1).

In contrast, it may be seen that, in Experimental Example (3), the transmittance of the sample did not change at the wavelength corresponding to the triple bond of carbon (C) and nitrogen (N). This result may indicate that acrylonitrile was changed through a crosslinking reaction into the form shown in Formula (2) (ladder-PAN).

Through these experiments the inventors confirmed that acrylonitrile exhibited a crosslinking reaction in the adhesive sample constituting the adhesive layer 15 through a heat treatment at a certain temperature.

Ultimately, in the dicing film 10 according to the inventive concept, the adhesive strength of the adhesive layer 15 constituting the dicing film 10 may sufficiently decrease after a heat treatment is performed thereon, and the semiconductor die may be easily separated from the dicing film 10. Accordingly, the effect of improving a pickup performance of the semiconductor die may be expected.

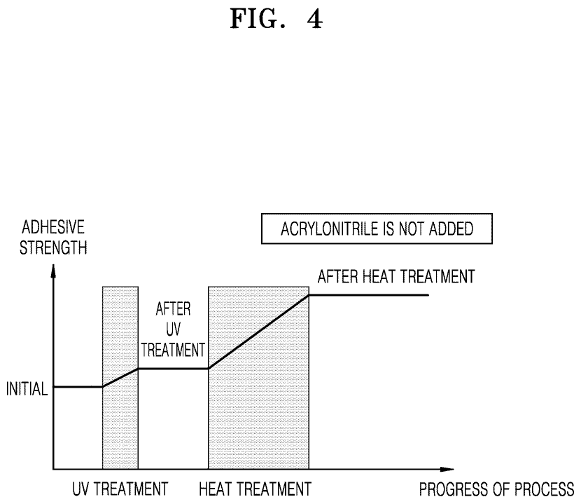

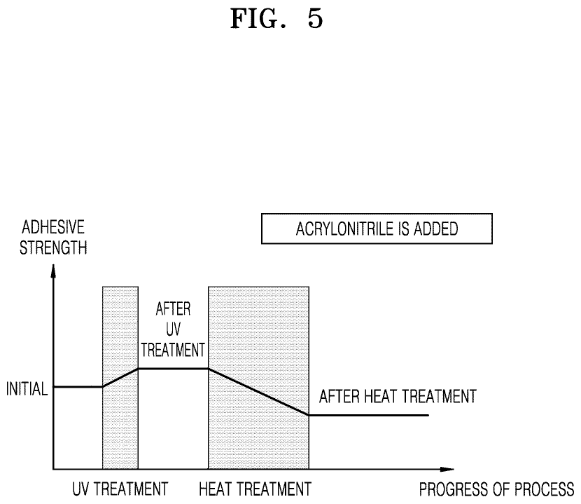

FIG. 4 is a graph showing a change in an adhesive strength when acrylonitrile is not added to the adhesive layer of the dicing film, and FIG. 5 is a graph showing a change in an adhesive strength when acrylonitrile is added to the adhesive layer of the dicing film.

Referring to FIGS. 4 and 5 together, the difference in adhesive strength when acrylonitrile is not added to the adhesive layer of the dicing film and when acrylonitrile is added to the adhesive layer of the dicing film may be confirmed.

In both the case of not adding acrylonitrile to the adhesive layer and the case of adding acrylonitrile to the adhesive layer (see FIGS. 4 and 5), it may be seen that the adhesive strength increased after a UV treatment was performed on the adhesive layer, compared to the initial adhesive strength. The UV treatment may lead to the curing of the acrylate polymer by the photoinitiator in the adhesive layer, but the ambient temperature rises to about 150° C. due to the high quality of LED UV irradiation, which is determined to actually increase the adhesive strength.

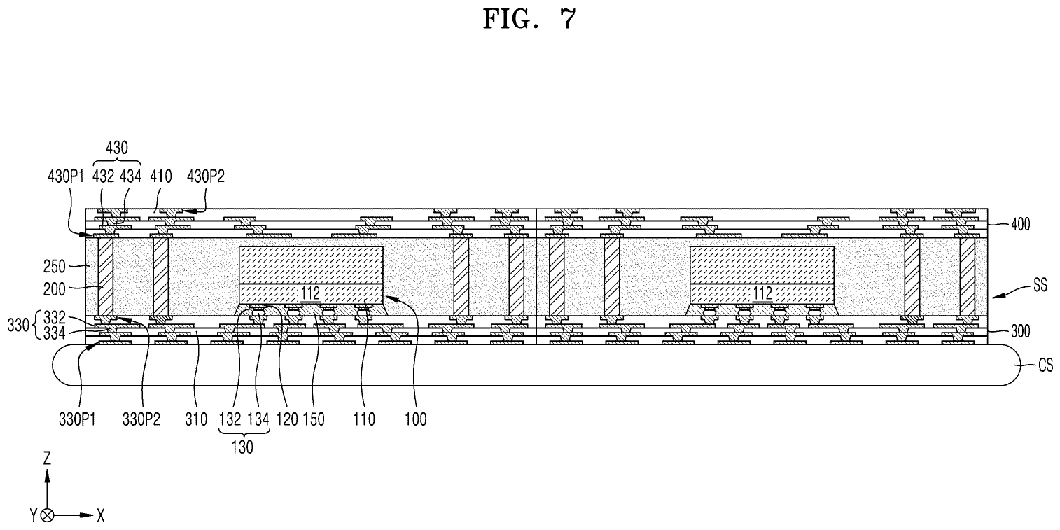

Like a general dicing film, when acrylonitrile is not added to the adhesive layer (see FIG. 4), the adhesive strength of the adhesive layer increases significantly when a heat treatment is performed after a UV treatment. This is determined to be due to an anchoring effect between the adhesive layer and the substrate structure (see SS of FIG. 7) according to a process temperature (about 250° C.) of a reflow process. Accordingly, after a high-temperature process such as the reflow process, the pickup performance is significantly lowered due to the high adhesive strength of the adhesive layer, and various problems such as residual adhesive residue may occur.

It may be seen that, when acrylonitrile was added to the adhesive layer (see FIG. 5) as in the dicing film according to the inventive concept, the adhesive strength of the adhesive layer decreased after a heat treatment was performed after a UV treatment, compared to the initial adhesive strength. This shows that acrylonitrile is additionally cured at the process temperature (about 250° C.) of the reflow process, which improves the cohesion of the adhesive layer during a high-temperature heat treatment and suppresses the increase in adhesive strength even after heat history.

Ultimately, in the dicing film according to the inventive concept, the adhesive strength of the adhesive layer constituting the dicing film may sufficiently decrease after a heat treatment is performed thereon, and the semiconductor die may be easily separated from the dicing film. Accordingly, the inventors might know that there was the effect of improving a pickup performance of the semiconductor die.

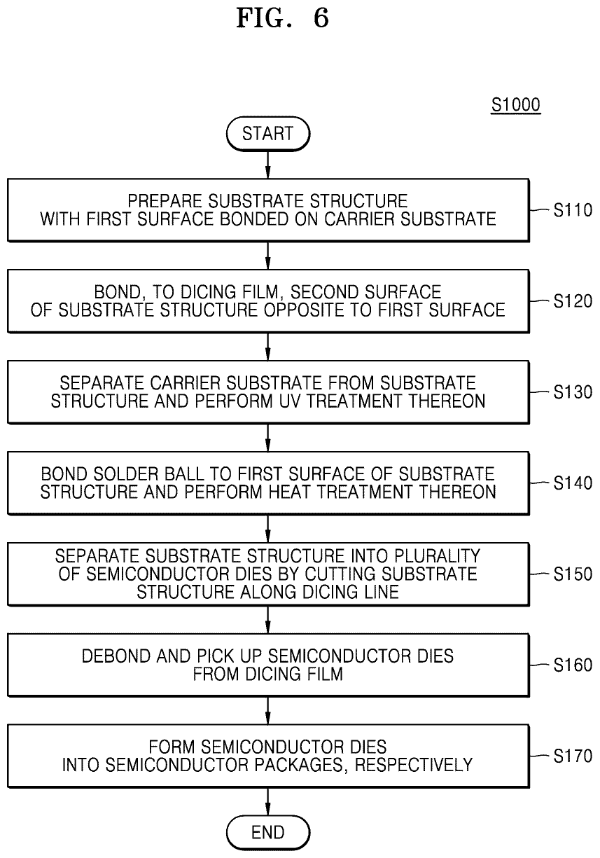

FIG. 6 is a flowchart of a method S1000 of manufacturing a semiconductor package, according to an embodiment.

Referring to FIG. 6, the method S1000 of manufacturing the semiconductor package may include process sequences of first to seventh operations S110 to S170.

When a certain embodiment may be implemented differently, a specific process order may be performed differently from the described order. For example, two consecutively described processes may be performed substantially at the same time or performed in an order opposite to the described order.

The method S1000 of manufacturing the semiconductor package, according to the inventive concept, may include a first operation S110 of preparing a substrate structure with a first surface bonded on a carrier substrate, a second operation S120 of bonding, to a dicing film, a second surface of the substrate structure opposite to the first surface, a third operation S130 of separating the carrier substrate from the substrate structure and performing a UV treatment thereon, a fourth operation S140 of bonding a solder ball to the first surface of the substrate structure and performing a heat treatment thereon, a fifth operation S150 of separating the substrate structure into a plurality of semiconductor dies by cutting the substrate structure along a dicing line, a sixth operation S160 of debonding and picking up the semiconductor dies from the dicing film, and a seventh operation S170 of respectively forming the semiconductor dies into semiconductor packages.

Technical features of the first to seventh operations S110 to S170 are described in detail with reference to FIGS. 7 to 16 to be described below.

FIGS. 7 to 16 are cross-sectional views illustrating the method of manufacturing the semiconductor packages, according to an embodiment.

Referring to FIG. 7, a substrate structure SS formed on a carrier substrate CS may be prepared.

The carrier substrate CS may be a semiconductor substrate, a glass substrate, a ceramic substrate, or a plastic substrate. In some embodiments, a release film (not shown) may be bonded to the carrier substrate CS and components of the substrate structure SS may be sequentially formed thereon. That is, the carrier substrate CS may be used as a support substrate to form the substrate structure SS.

Specifically, the substrate structure SS may include a first semiconductor chip 100, a conductive post 200 around the first semiconductor chip 100, a first wiring structure 300 below the first semiconductor chip 100, and a second wiring structure 400 on the first semiconductor chip 100.

The substrate structure SS may have a package-on-package (POP) structure. Specifically, the substrate structure SS may be a fan-out semiconductor package in which the horizontal width and horizontal area of the first wiring structure 300 are greater than the horizontal width and horizontal area of the first semiconductor chip 100. In some embodiments, the substrate structure SS may be a fan-out wafer level package (FOWLP) or a fan-out panel level package (FOPLP).

In some embodiments, the first wiring structure 300 and the second wiring structure 400 may be formed by a redistribution process. Accordingly, the first wiring structure 300 and the second wiring structure 400 may be respectively referred to as a first redistribution structure and a second redistribution structure, or may be respectively referred to as a lower redistribution structure and an upper redistribution structure.

The first wiring structure 300 may include a first redistribution insulating layer 310 and a plurality of first redistribution patterns 330. The first redistribution insulating layer 310 may surround the first redistribution patterns 330. In some embodiments, the first wiring structure 300 may include a plurality of stacked first redistribution insulating layers 310.

The first redistribution patterns 330 may include a plurality of first redistribution line patterns 332 and a plurality of first redistribution vias 334. The first redistribution patterns 330 may each be formed of and/or include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or may be alloy of the metal described above, but the inventive concept is not limited thereto.

The first redistribution line patterns 332 may be disposed on at least one of the upper surface and the lower surface of the first redistribution insulating layer 310. For example, when the first wiring structure 300 includes a plurality of stacked first redistribution insulating layers 310, the first redistribution line patterns 332 may be disposed on the upper surface of the uppermost first redistribution insulating layer 310 and the lower surface of the lowermost first redistribution insulating layer 310, and may be between the first redistribution insulating layers 310 adjacent to each other.

The first redistribution vias 334 may pass through the first redistribution insulating layer 310 and be connected to some of the first redistribution line patterns 332. In some embodiments, the first redistribution vias 334 may each have a tapered shape extending so that a horizontal width increases from the bottom to the top.

In some embodiments, some of the first redistribution line patterns 332 may be integrally formed together with some of the first redistribution vias 334. For example, the first redistribution line pattern 332 and the first redistribution via 334 in contact with the lower surface of the first redistribution line pattern 332 may be integrally formed together.

Some of the first redistribution patterns 330 disposed adjacent to the lower surface of the first wiring structure 300 may be referred to as a plurality of first lower surface connection pads 330P1, and some of the first redistribution patterns 330 disposed adjacent to the upper surface of the first wiring structure 300 may be referred to as a plurality of first upper surface connection pads 330P2. That is, the first lower surface connection pads 330P1 may be some of the first redistribution line patterns 332 disposed adjacent to the lower surface of the first wiring structure 300, and the first upper surface connection pads 330P2 may be some of the first redistribution line patterns 332 disposed adjacent to the upper surface of the first wiring structure 300.

The first upper surface connection pads 330P2 may be disposed on the upper surface of the first redistribution insulating layer 310. For example, when the first wiring structure 300 includes the stacked first redistribution insulating layers 310, the first upper surface connection pads 330P2 may be disposed on the upper surface of the uppermost first redistribution insulating layer 310.

At least one first semiconductor chip 100 may be mounted on the first wiring structure 300. That is, one or more first semiconductor chips 100 may be provided. The first semiconductor chip 100 may include a semiconductor substrate 110 having an active surface and an inactive surface facing each other, a semiconductor device 112 on the active surface of the semiconductor substrate 110, and a plurality of chip pads 120 on the first semiconductor chip 100.

A plurality of chip connection members 130 may be between the chip pads 120 of the first semiconductor chip 100 and some of the first upper surface connection pads 330P2 of the first wiring structure 300. For example, the chip connection members 130 may each be a solder ball or a micro bump. The first semiconductor chip 100 and the first redistribution pattern 330 of the first wiring structure 300 may be electrically connected through the chip connection members 130. The chip connection members 130 may include an under bump metal (UBM) layer 132 disposed on the chip pads 120, and a conductive connection member 134 covering the UBM layer 132. The chip connection members 130 may each be formed of and/or include, for example, copper (Cu), aluminum (Al), silver (Ag), tin (Tin), gold (Au), or solder, but the inventive concept is not limited thereto.

The semiconductor substrate 110 may be formed of and/or include, for example, a semiconductor material, such as silicon (Si) or germanium (Ge). Alternatively, the semiconductor substrate 110 may be formed of and/or include a compound semiconductor material, such as silicon carbide (SiC), gallium arsenide (GaAs), indium arsenide (InAs), and indium phosphide (InP). The semiconductor substrate 110 may include a well doped with impurities, which is a conductive region. The semiconductor substrate 110 may have various device isolation structures, such as a shallow trench isolation (STI) structure.

A semiconductor device 112 including a plurality of various types of individual devices may be formed on the active surface of the semiconductor substrate 110. The individual devices may be electrically connected to the conductive region of the semiconductor substrate 110. The semiconductor device 112 may further include a conductive wiring or a conductive plug, which electrically connects the individual devices to the conductive region of the semiconductor substrate 110. In addition, the individual devices may be respectively electrically separated from other neighboring individual devices by an insulating film.

In some embodiments, the first semiconductor chip 100 may include a logic device. For example, the first semiconductor chip 100 may be a central processing unit (CPU) chip, a graphics processing unit (GPU) chip, or an application processor (AP) chip. In other embodiments, when the substrate structure SS includes a plurality of first semiconductor chips 100, one of the first semiconductor chips 100 may be a CPU chip, a GPU chip, or an AP chip, and another of the first semiconductor chips 100 may be a memory semiconductor chip including a memory device.

For example, the memory device may be a non-volatile memory device, such as flash memory, phase-change random access memory (PRAM), magnetoresistive random access memory (MRAM), ferroelectric random access memory (FeRAM), or resistive random access memory (RRAM). In some embodiments, the memory device may be a volatile memory device, such as dynamic random access memory (DRAM) or static random access memory (SRAM).

The second wiring structure 400 may include a second redistribution insulating layer 410 and a plurality of second redistribution patterns 430. The second redistribution insulating layer 410 may surround the second redistribution patterns 430.

In some embodiments, the second wiring structure 400 may include a plurality of stacked second redistribution insulating layers 410. The second redistribution patterns 430 may include a plurality of second redistribution line patterns 432 and a plurality of second redistribution vias 434. The second redistribution patterns 430 may be formed of and/or include metal or a metal alloy. In some embodiments, the second redistribution patterns 430 may be formed by stacking metal or a metal alloy on a seed layer.

The second redistribution line patterns 432 may be disposed on at least one of the upper surface and the lower surface of the second redistribution insulating layer 410. For example, when the second wiring structure 400 includes a plurality of stacked second redistribution insulating layers 410, the second redistribution line patterns 432 may be disposed on the upper surface of the uppermost second redistribution insulating layer 410 and the lower surface of the lowermost second redistribution insulating layer 410, and may be between the second redistribution insulating layers 410 adjacent to each other.

Some of the second redistribution patterns 430 disposed adjacent to the lower surface of the second wiring structure 400 may be referred to as a plurality of second lower surface connection pads 430P1, and some of the second redistribution patterns 430 disposed adjacent to the upper surface of the second wiring structure 400 may be referred to as a plurality of second upper surface connection pads 430P2. That is, the second lower surface connection pads 430P1 may be some of the second redistribution line patterns 432 disposed adjacent to the lower surface of the second wiring structure 400, and the second upper surface connection pads 430P2 may be some of the second redistribution line patterns 432 disposed adjacent to the upper surface of the second wiring structure 400. In other embodiments, the second lower surface connection pads 430P1 may be some of the second redistribution vias 434 disposed adjacent to the lower surface of the second wiring structure 400.

The second lower surface connection pads 430P1 may be disposed on the lower surface of the second redistribution insulating layer 410. For example, when the second wiring structure 400 includes the stacked second redistribution insulating layers 410, the second lower surface connection pads 430P1 may be disposed on the lower surface of the lowermost second redistribution insulating layer 410.

The second upper surface connection pads 430P2 may be disposed on the upper surface of the second redistribution insulating layer 410. For example, when the second wiring structure 400 includes the stacked second redistribution insulating layers 410, the second upper surface connection pads 430P2 may be disposed on the upper surface of the uppermost second redistribution insulating layer 410.

The second redistribution vias 434 may pass through the second redistribution insulating layer 410 and be connected in contact with some of the second redistribution line patterns 432. In some embodiments, some of the second redistribution line patterns 432 may be integrally formed together with some of the second redistribution vias 434. For example, the second redistribution line pattern 432 and the second redistribution via 434 in contact with the lower surface of the second redistribution line pattern 432 may be integrally formed together.

In some embodiments, the second redistribution vias 434 may each have a tapered shape extending so that a horizontal width decreases from the top to the bottom. That is, the first redistribution vias 334 and the second redistribution vias 434 extend in the same direction and may each have a shape in which a horizontal width decreases, but the inventive concept is not limited thereto.

The first redistribution insulating layer 310, the first redistribution pattern 330, the first redistribution line pattern 332, and the first redistribution via 334 may be respectively referred to as a first insulating layer, a first wiring pattern, a first wiring line pattern, and a first wiring via. In addition, the second redistribution insulating layer 410, the second redistribution pattern 430, the second redistribution line pattern 432, and the second redistribution via 434 may be respectively referred to as a second insulating layer, a second wiring pattern, a second wiring line pattern, and a second wiring via.

An encapsulant 250 may surround the first semiconductor chip 100 on the upper surface of the first wiring structure 300. The encapsulant 250 may fill a space between the first wiring structure 300 and the second wiring structure 400. For example, the encapsulant 250 may be a molding member including an epoxy mold compound (EMC). The encapsulant 250 may further include a filler.

In some embodiments, an underfill layer 150 surrounding the chip connection members 130 may be between the first semiconductor chip 100 and the first wiring structure 300. In some embodiments, the underfill layer 150 may fill a space between the first semiconductor chip 100 and the first wiring structure 300 and may cover a portion of the lower surface of the first semiconductor chip 100. The underfill layer 150 may be formed by, for example, a capillary underfill process and may include epoxy resin.

In some embodiments, the side surface of the first wiring structure 300, the side surface of the encapsulant 250, and the side surface of the second wiring structure 400 may be aligned with each other in the vertical direction so as to be coplanar.

A plurality of conductive posts 200 may pass through the encapsulant 250 and electrically connect the first and second wiring structures 300 and 400 to each other. The encapsulant 250 may surround the conductive posts 200.

The conductive posts 200 may be between the first wiring structure 300 and the second wiring structure 400 so as to be spaced apart from the first semiconductor chip 100 in the horizontal direction. For example, the conductive posts 200 may be spaced apart from the first semiconductor chip 100 in the horizontal direction, and may be arranged around the first semiconductor chip 100 in the outer area of the first wiring structure 300.

The conductive posts 200 may be between the first upper surface connection pads 330P2 and the second lower surface connection pads 430P1. The lower surfaces of the conductive posts 200 may be in contact with the first upper surface connection pads 330P2 of the first wiring structure 300 and be electrically connected to the first redistribution patterns 330, and the upper surfaces of the conductive posts 200 may be in contact with the second lower surface connection pads 430P1 of the second wiring structure 400 and be electrically connected to the second redistribution patterns 430.

The lower surfaces of the conductive posts 200 may be in contact with the upper surfaces of the first upper surface connection pads 330P2. The upper surfaces of the conductive posts 200 may be in contact with the lower surfaces of the second lower surface connection pads 430P1.

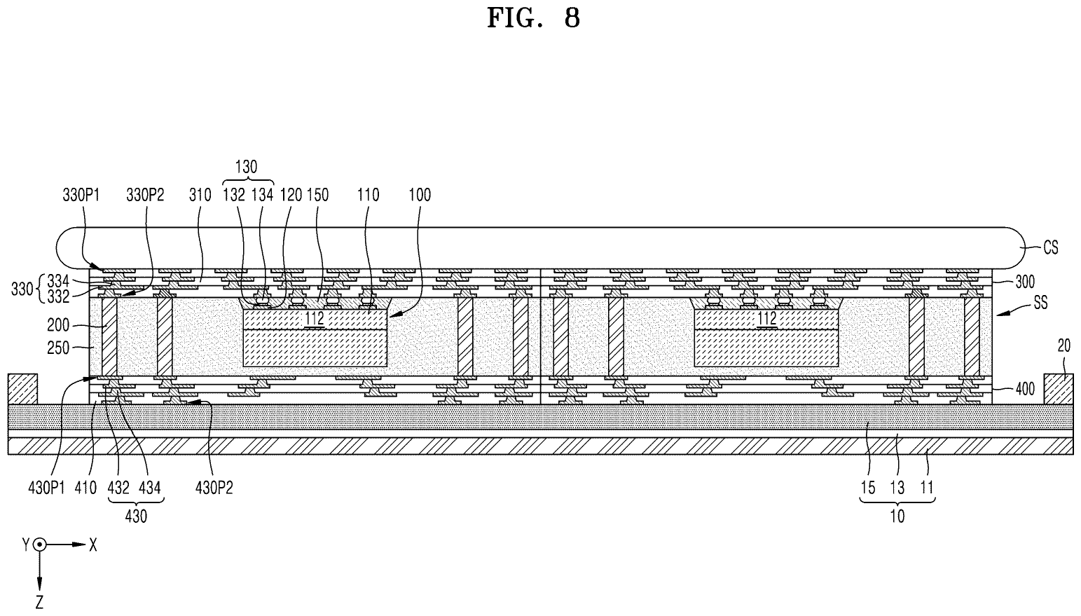

Referring to FIG. 8, the exposed surface of the substrate structure SS may be bonded to the dicing film 10.

The exposed surface of the substrate structure SS to which the carrier substrate CS is bonded may be mounted so as to be attached to the adhesive layer 15 of the dicing film 10. As illustrated in FIG. 8, the edge portion of the adhesive layer 15 of the dicing film 10 may be fixed to a lower portion of a frame 20. The frame 20 may have a circular ring shape, but the inventive concept is not limited thereto. When the substrate structure SS to which the carrier substrate CS is bonded is attached to the adhesive layer 15 of the dicing film 10, the second wiring structure 400 formed on the substrate structure SS may be bonded to face the adhesive layer 15.

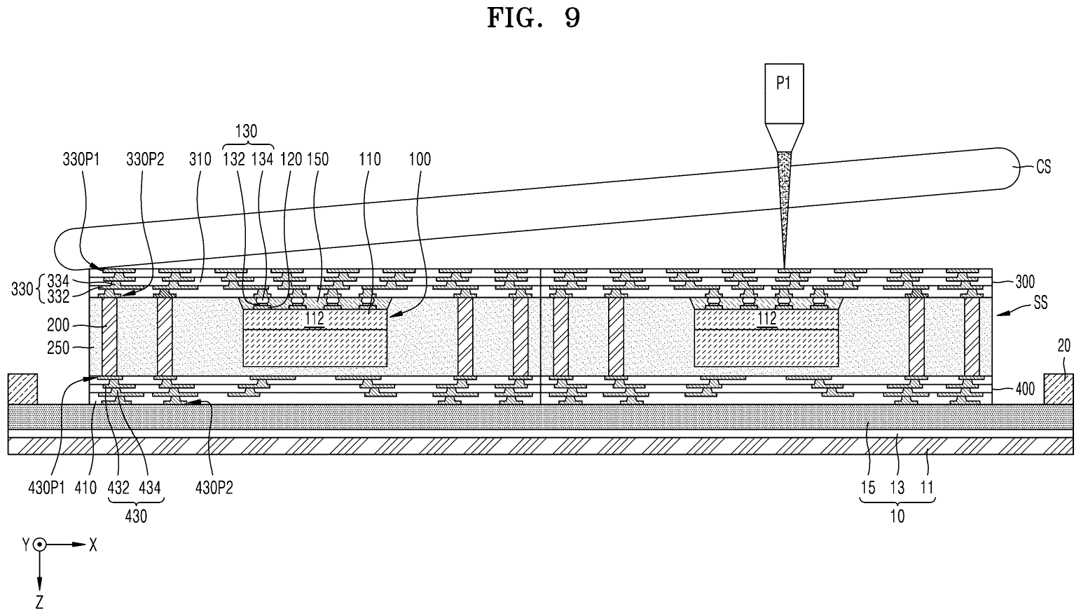

Referring to FIG. 9, the carrier substrate CS may be separated from the substrate structure SS.

In order to separate and remove the carrier substrate CS, a laser P1 may be emitted to the carrier substrate CS. The emission of the laser P1 may weaken the bonding force between the substrate structure SS and the carrier substrate CS, and the carrier substrate CS may be completely separated from the substrate structure SS.

In order to facilitate the separation of the carrier substrate CS, an adhesive layer (not shown) may be between the carrier substrate CS and the substrate structure SS. The adhesive layer may be in a liquid or gel form that may be easily deformed by certain heat caused by the emission of the laser P1.

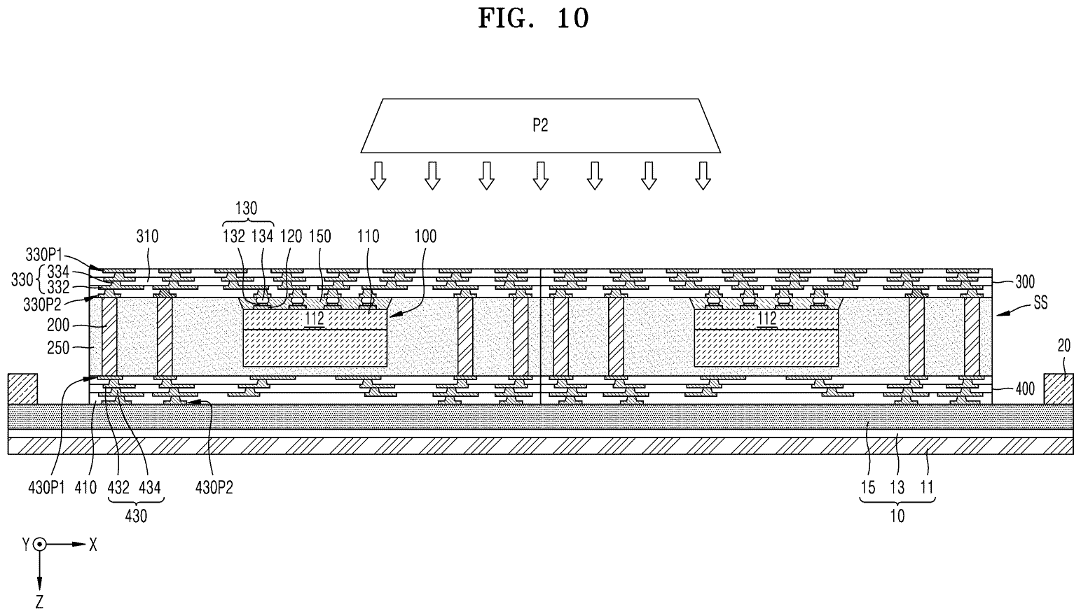

Referring to FIG. 10, UV light P2 may be emitted to the exposed surface of the substrate structure SS from which the carrier substrate (see CS of FIG. 9) is separated.

The UV light P2 may remove adhesive residues that may remain on the exposed surface of the substrate structure SS from which the carrier substrate (see CS of FIG. 9) is separated. As described above, the adhesive layer (not shown) may be between the carrier substrate (see CS of FIG. 9) and the substrate structure SS, and the adhesive layer may be in a liquid or gel form. Accordingly, for complete separation, the UV light P2 may be emitted to the exposed surface of the substrate structure SS.

As described above, due to a treatment using the UV light P2, the adhesive strength of the adhesive layer 15 constituting the dicing film 10 increases, compared to the initial adhesive strength.

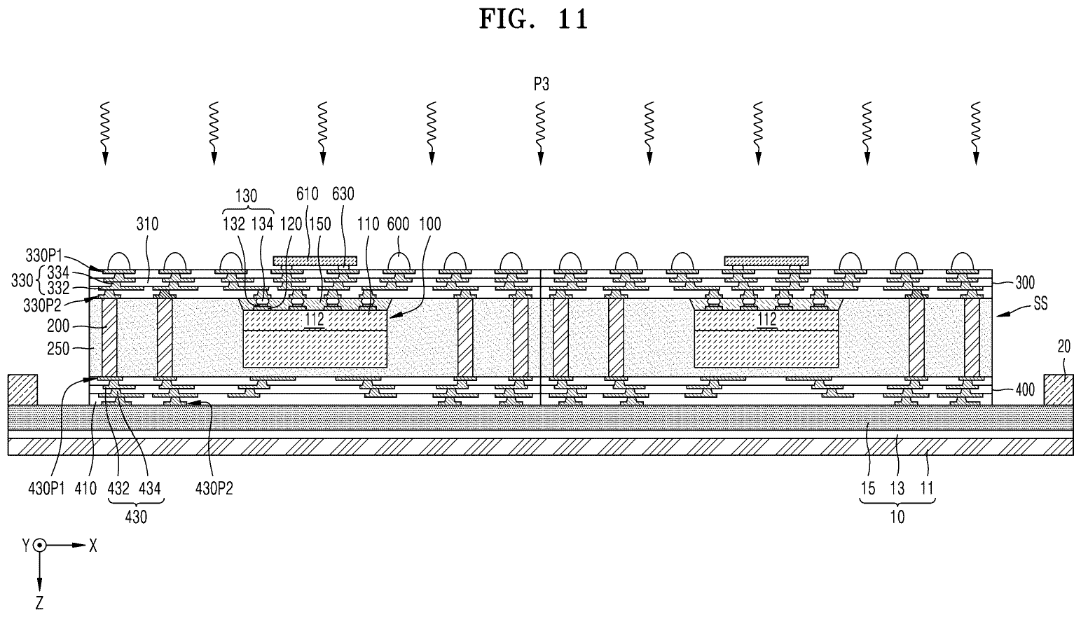

Referring to FIG. 11, a plurality of external connection terminals 600 may be bonded to some of the first lower surface connection pads 330P1, and passive devices 610 may be bonded to others of the first lower surface connection pads 330P1.

The external connection terminals 600 may be formed on the upper surface of the first wiring structure 300. The external connection terminals 600 may include, for example, a solder ball, a conductive bump, a conductive paste, a ball grid array (BGA), a lead grid array (LGA), a pin grid array (PGA), or any combination thereof.

The passive device 610 may include at least one device selected from the group consisting of a resistor, a capacitor, an inductor, a thermistor, an oscillator, a ferrite bead, an antenna, and a varistor. For example, the passive device 610 may include a multi layer ceramic capacitor (MLCC), a low inductance chip capacitor (LICC), a land side capacitor (LSC), an integrated passive device (IPD), etc., but the inventive concept is not limited thereto.

A reflow process may be performed to bond the external connection terminals 600 and the passive devices 610 to the first lower surface connection pads 330P1. For example, the reflow process may be a heat treatment P3 that is performed in a temperature range of about 175° C. to about 250° C.

After the solder constituting the external connection terminals 600 is melted by the reflow process, the solder may be arranged in a ball shape on the first lower surface connection pads 330P1 due to surface tension without collapsing. In some embodiments, an intermetallic compound may be formed at an interface between the external connection terminals 600 and the first lower surface connection pads 330P1.

As described above, due to the heat treatment P3, the adhesive strength of the adhesive layer 15 constituting the dicing film 10 decreases, compared to the initial adhesive strength.

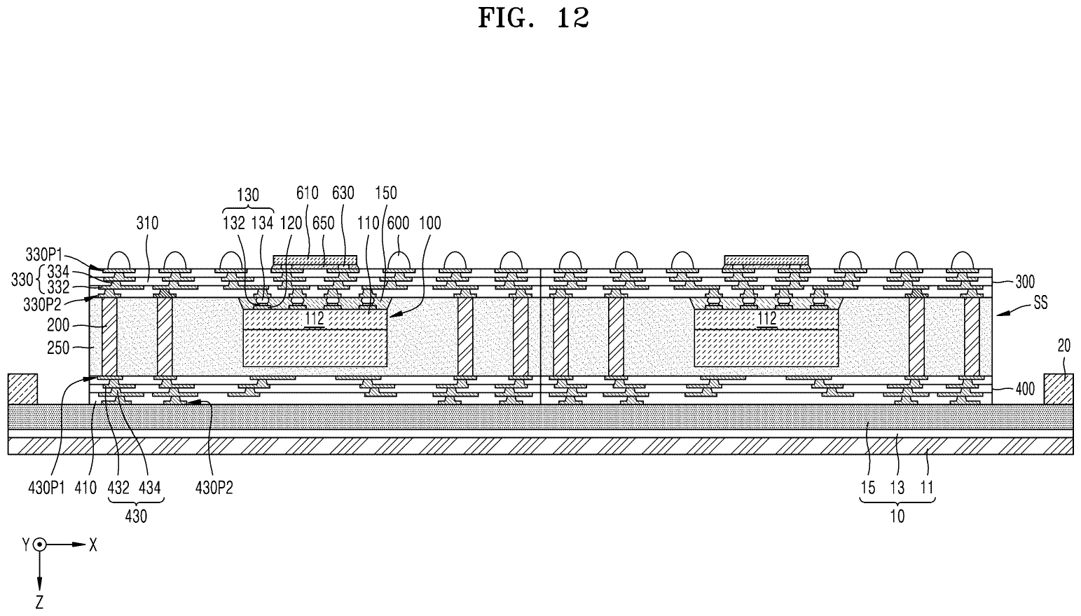

Referring to FIG. 12, a space between the passive device 610 and the first wiring structure 300 may be filled with an underfill layer 650.

The underfill layer 650 may surround the sidewall of the solder bump 630 disposed below the passive device 610 and fill a gap between the adjacent solder bumps 630. In the process of electrically connecting the passive device 610 to the solder bump 630, a gap may be formed between the passive device 610 and the solder bump 630. Because the gap may cause problems in the reliability of the connection between the passive device 610 and the solder bump 630, the underfill layer 650 may be injected and cured so as to reinforce the connection.

The passive device 610 may be more stably fixed on the solder bump 630 by the underfill layer 650. Despite the difference in thermal expansion coefficient between the passive device 610 and the solder bump 630, the passive device 610 and the solder bump 630 may not be electrically separated from each other.

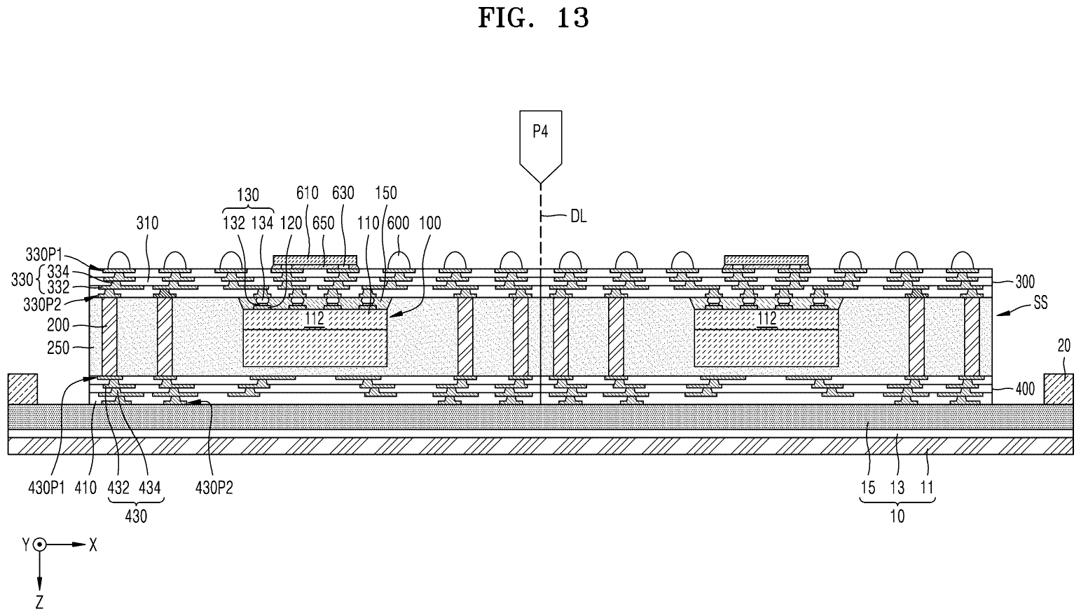

Referring to FIG. 13, various components including the first wiring structure 300 of the substrate structure SS may be cut along a dicing line DL, as indicated by P4.

Because the substrate structure SS may be a fan-out wafer level package or a fan-out panel level package, various types of material films, including the first wiring structure 300, may be cut along the dicing line DL and physically separated into individual semiconductor dies, as indicated by P4. Although only one dicing line DL is illustrated in FIG. 13, the inventive concept is not limited thereto.

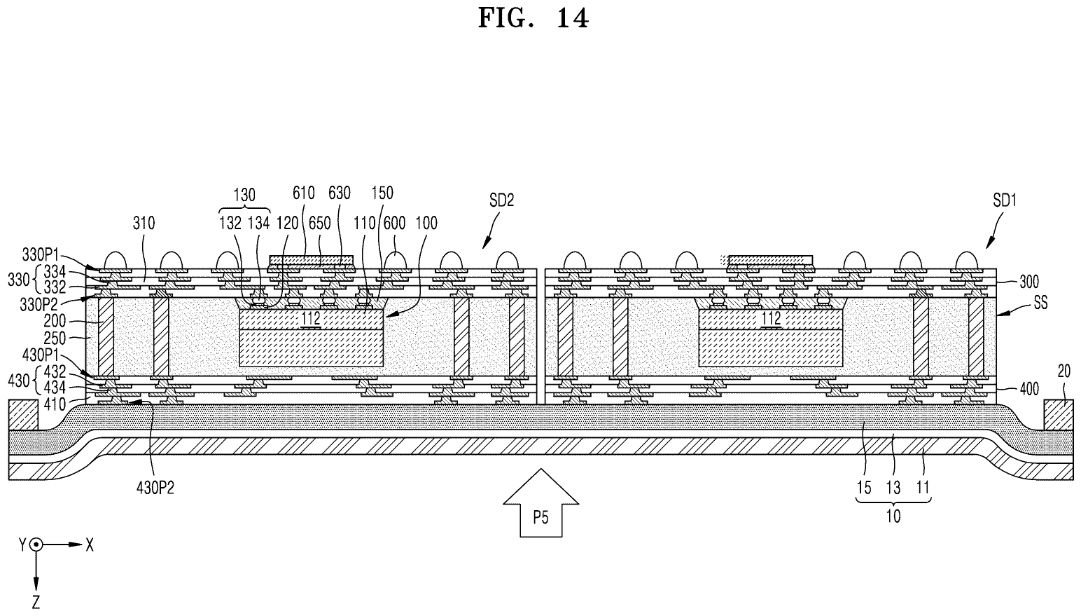

Referring to FIG. 14, pressure P5 may be provided to the lower portion of the dicing film 10 so as to expand the surface area of the dicing film 10.

In some embodiments, a jig (not shown) may be attached to the lower portion of the dicing film 10 and the jig may be pushed up so as to expand the dicing film 10. That is, mechanical pressure P5 may be provided to the lower portion of the dicing film 10.

As the dicing film 10 expands, the substrate structure (see SS of FIG. 13) may be physically separated into first and second semiconductor dies SD1 and SD2 with respect to the dicing line (see DL of FIG. 13). Although only one first semiconductor die SD1 and only one second semiconductor die SD2 are illustrated in FIG. 14, the number of semiconductor dies is not limited thereto.

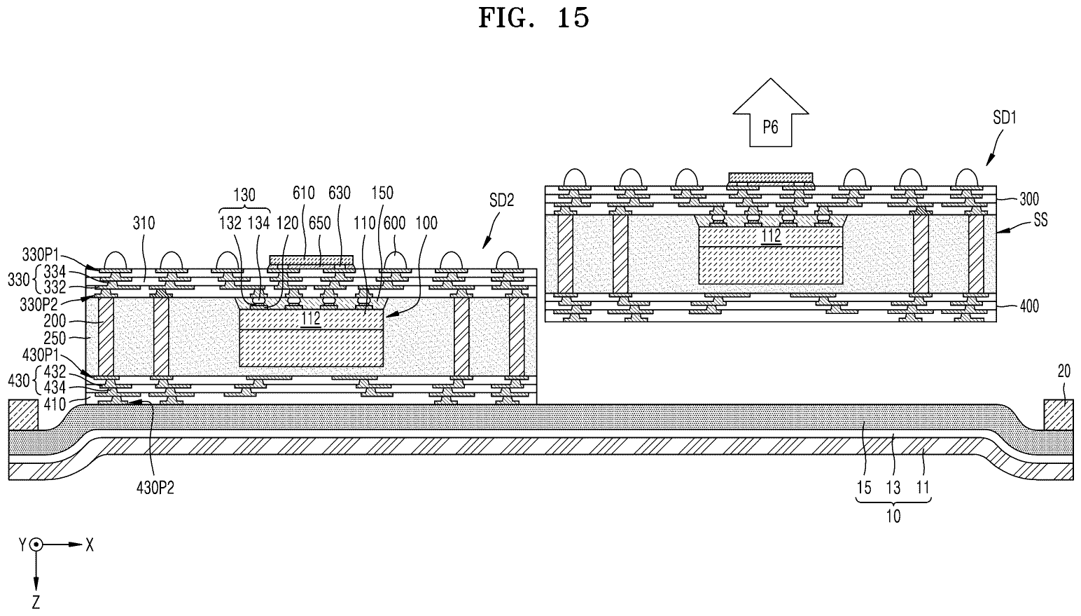

Referring to FIG. 15, the first semiconductor die SD1 may be picked up from the dicing film 10 by using a pickup device, as indicated by P6.

Because the adhesive strength of the adhesive layer 15 constituting the dicing film 10 sufficiently decreases due to the previous heat treatment (see P3 of FIG. 11), compared to the initial adhesive strength, the first semiconductor die SD1 may be easily picked up from the dicing film 10, as indicated by P6. Accordingly, there is an effect of improving the pickup performance of the first semiconductor die SD1.

In some embodiments, a wet cleaning process may be performed to remove adhesive residues that may remain on a surface exposed when the dicing film 10 is removed from the first semiconductor die SD1. The wet cleaning process may be performed by using an organic solvent or an inorganic solvent according to the material of the adhesive layer 15 constituting the dicing film 10.

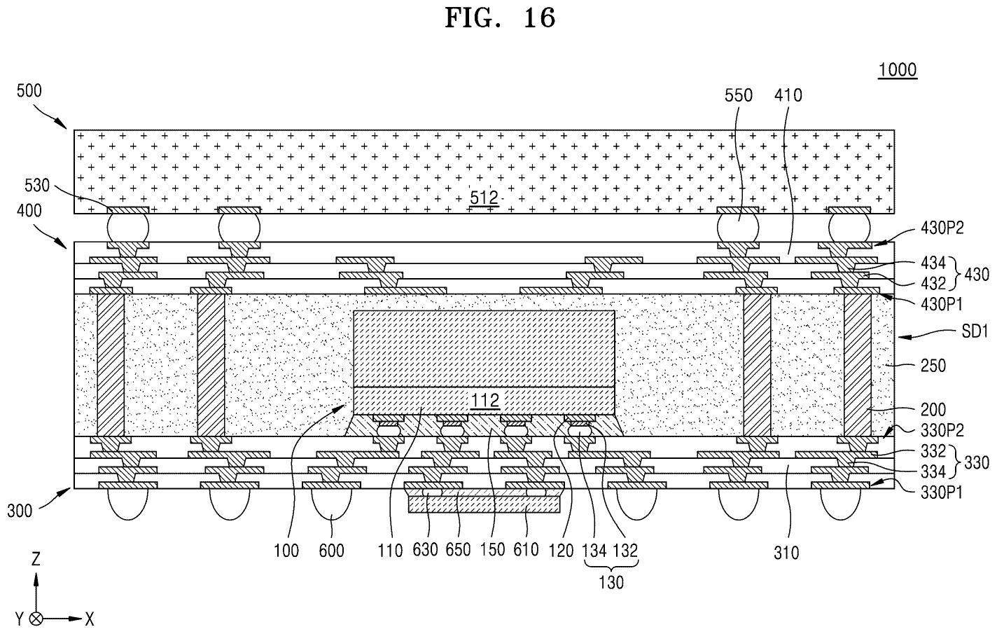

Referring to FIG. 16, the second semiconductor chip 500 may be mounted to be electrically connected to the second wiring structure 400 of the first semiconductor die SD1.

The second semiconductor chip 500 may be mounted on the second wiring structure 400 so that a plurality of upper connection pads 530 face the second wiring structure 400. The second semiconductor chip 500 may be electrically connected to the first redistribution patterns 330 of the first wiring structure 300 through a plurality of internal connection terminals 550 bonded to the upper connection pads 530, a plurality of second redistribution patterns 430, and a plurality of conductive posts 200. In this manner, the semiconductor package 1000 may be completed.

As described above, in the method of manufacturing the semiconductor package 1000 according to the inventive concept, the adhesive strength of the adhesive layer (see 15 of FIG. 15) constituting the dicing film (see 10 of FIG. 15) may sufficiently decrease after the heat treatment is performed thereon, and the semiconductor die may be easily separated from the dicing film (see 10 of FIG. 15). Accordingly, there is an effect of improving the pickup performance of the semiconductor die.

In addition, the semiconductor wafer may be transferred by using the dicing film (see 10 of FIG. 1) according to the inventive concept. That is, by transferring the semiconductor wafer by using the dicing film (see 10 of FIG. 1) as a transfer substrate, the semiconductor package may be manufactured without using a carrier substrate (or using a carrier substrate less frequently).

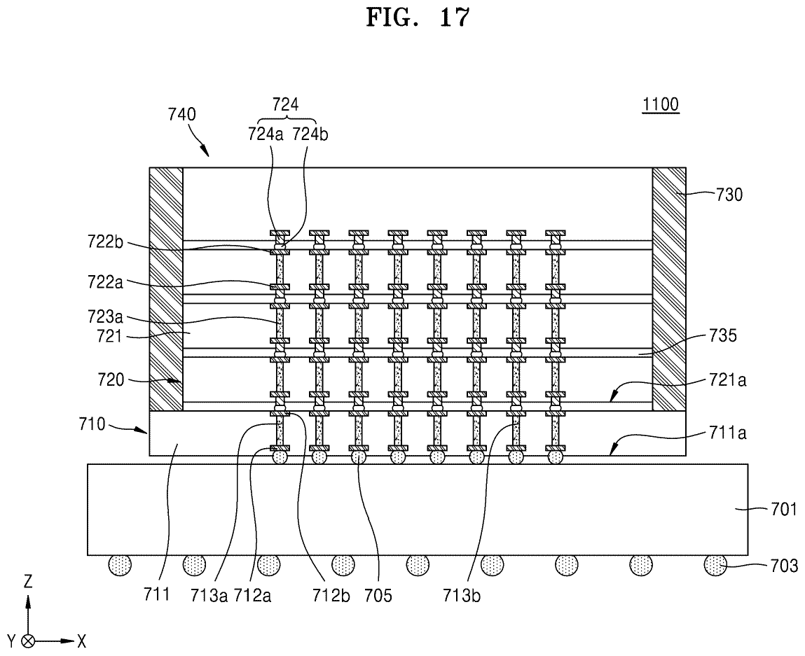

FIGS. 17 to 19 are diagrams illustrating other semiconductor packages manufactured by the method of manufacturing the semiconductor package, according to the inventive concept.

Referring to FIG. 17, a semiconductor package 1100 may include a stacked semiconductor chip 740 stacked on a package substrate 701.

The package substrate 701 may be a printed circuit board (PCB). In addition, a solder bump 703, which is an external connection terminal, may be formed on the lower surface of the package substrate 701.

The stacked semiconductor chip 740 may include a first semiconductor chip 710 and a plurality of second semiconductor chips 720 mounted on the first semiconductor chip 710. The second semiconductor chips 720 may be sequentially stacked on the first semiconductor chip 710 in the vertical direction (the Z direction). The width of the first semiconductor chip 710 may be greater than the width of each of the second semiconductor chips 720.

Although FIG. 17 illustrates that the stacked semiconductor chip 740 includes four second semiconductor chips 720, but the inventive concept is not limited thereto. For example, the stacked semiconductor chip 740 may include two or more second semiconductor chips 720. The first semiconductor chip 710 and the second semiconductor chips 720 may be manufactured by using the dicing film (see 10 of FIG. 1) according to the inventive concept.

The first semiconductor chip 710 may include a first pad 712a and a second pad 712b respectively on both surfaces of the first semiconductor substrate 711. The first pad 712a and the second pad 712b may be electrically connected to each other by using a first through-via structure 713a. The first pad 712a may be electrically connected to the package substrate 701 by using a solder bump 705, which is an external connection terminal. An active surface 711a of the first semiconductor chip 710 may be disposed downward. The first pad 712a may be a top pad and the second pad 712b may be a bottom pad.

The second semiconductor chips 720 may each include a third pad 722a and a fourth pad 722b respectively on both surfaces of the second semiconductor substrate 721. The third pad 722a and the fourth pad 722b may be electrically connected to each other by using a second through-via structure 723a. The third pad 722a may electrically connect the second semiconductor chips 720 to each other by using an internal connection terminal 724. The internal connection terminal 724 may include an internal connection pad 724a and an internal bump 724b. An active surface 721a of each of the second semiconductor chips 720 may be disposed downward. The third pad 722a may be a top pad and the fourth pad 722b may be a bottom pad.

The stacked semiconductor chip 740 may be bonded to the second semiconductor chips 720 by an adhesive layer 735. The second semiconductor chips 720 may be molded on the first semiconductor chip 710 by a molding layer 730.

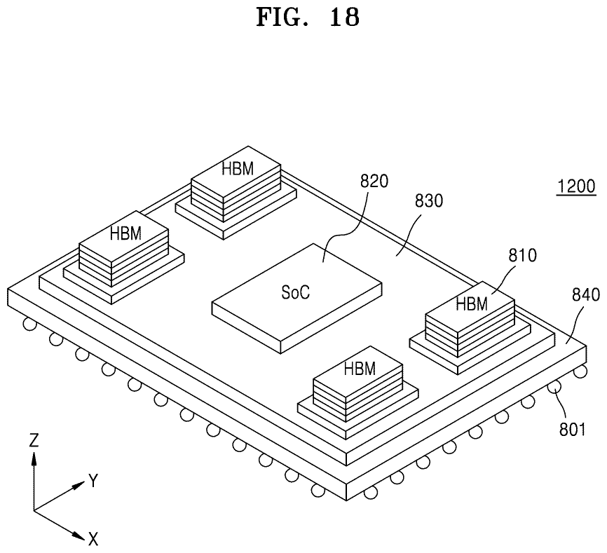

Referring to FIG. 18, a semiconductor package 1200 may include a plurality of stacked memory chips 810 and a system-on-chip 820.

The stacked memory chips 810 and the system-on-chip 820 may be stacked on an interposer chip 830, and the interposer chip 830 may be stacked on a package substrate 840. The interposer chip 830 may be manufactured by using the dicing film (see 10 of FIG. 1) according to the inventive concept.

The semiconductor package 1200 may transmit and receive signals with other external packages or electronic devices through a solder ball 801 bonded to the lower portion of the package substrate 840.

The stacked memory chips 810 may each be implemented based on a high bandwidth memory (HBM) standard. However, the inventive concept is not limited thereto, and the stacked memory chips 810 may each be implemented based on graphics double data rate (GDDR), hardware management console (HMC), or wide input/output (I/O) standards. The stacked memory chips 810 may each be manufactured by using the dicing film (see 10 of FIG. 1) according to the inventive concept.

The system-on-chip 820 may include at least one processor selected from an AP, a CPU, and a GPU, and a memory controller that controls the stacked memory chips 810. The system-on-chip 820 may transmit and receive signals to and from the corresponding stacked memory chip through the memory controller.

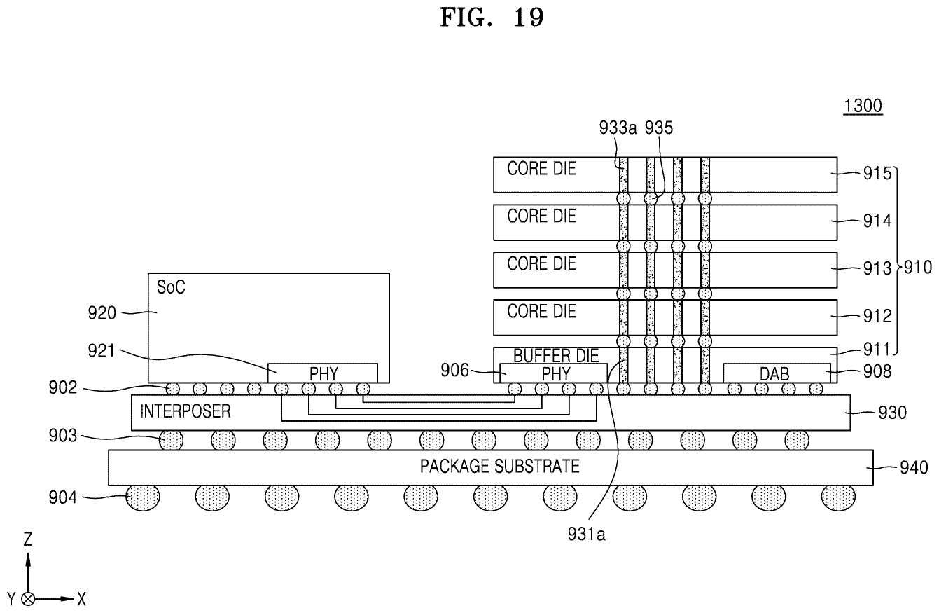

Referring to FIG. 19, the semiconductor package 1300 may include a stacked memory chip 910, a system-on-chip 920, an interposer chip 930, and a package substrate 940.

The interposer chip 930 may be manufactured by using the dicing film (see 10 of FIG. 1) according to the inventive concept. In addition, the stacked memory chip 910 may include a buffer die 911 and core dies 912 to 915. The stacked memory chip 910 may be manufactured by using the dicing film (see 10 of FIG. 1) according to the inventive concept.

The core dies 912 to 915 may each include memory cells that store data. The buffer die 911 may include a physical layer 906 and a direct access area 908. The physical layer 906 may be electrically connected to the physical layer 921 of the system-on-chip 920 through the interposer chip 930. The stacked memory chip 910 may receive signals from the system-on-chip 920 through the physical layer 906, or may transmit signals to the system-on-chip 920.

The direct access area 908 may provide an access path to test the stacked memory chip 910 without passing through system-on-chip 920. The direct access area 908 may include a conductive means (e.g., a port or a pin) that allow direct communication with an external test device. Test signals received through the direct access area 908 may be transmitted to the core dies 912 to 915 through the through-via structures. In order to test the core dies 912 to 915, data read from the core dies 912 to 915 may be transmitted to a test device through the through-via structures and the direct access area 908. Accordingly, direct access testing may be performed on the core dies 912 to 915.

The buffer die 911 and the core dies 912 to 915 may be electrically connected to each other through through-via structures 931a and 933a and bumps 935. The buffer die 911 and the core dies 912 to 915 may be manufactured by using the dicing film (see 10 of FIG. 1) according to the inventive concept.

For example, the buffer die 911 may include a first through-via structure 931a. The core dies 912 to 915 may each include a second through-via structure 933a. The buffer die 911 may receive, from the system-on-chip 920, signals provided to each channel through bumps 902 allocated for each channel, or may transmit signals to the system-on-chip 920 through the bumps 902. For example, the bumps 902 may be micro bumps.

The system-on-chip 920 may execute applications supported by the semiconductor package 1300 by using the stacked memory chip 910. The system-on-chip 920 may be manufactured by using the dicing film (see 10 of FIG. 1) according to the inventive concept.

The system-on-chip 920 may control overall operations of the stacked memory chip 910. The system-on-chip 920 may include a physical layer 921. The physical layer 921 may include an interface circuit that transmits and receives signals to and from the physical layer 906 of the stacked memory chip 910. The system-on-chip 920 may provide various signals to the physical layer 906 through the physical layer 921. Signals provided to the physical layer 906 may be transmitted to the core dies 912 to 915 through the interface circuit of the physical layer 906 and the through-via structures 931a and 933a.

The interposer chip 930 may connect the stacked memory chip 910 to the system-on-chip 920. The interposer chip 930 may connect the physical layer 906 of the stacked memory chip 910 to the physical layer 921 of the system-on-chip 920, and may provide physical paths formed by using conductive materials. Accordingly, the stacked memory chip 910 and the system-on-chip 920 may be stacked on the interposer chip 930 and may transmit and receive signals to each other.

Bumps 903 may be bonded to the upper portion of the package substrate 940, and solder balls 904 may be bonded to the lower portion of the package substrate 940. For example, the bumps 903 may be flip chip bumps. The interposer chip 930 may be stacked on the package substrate 940 through the bumps 903. The semiconductor package 1300 may transmit and receive signals to and from other external packages or electronic devices through the solder ball 904.

While the inventive concept has been particularly shown and described with reference to embodiments thereof, it will be understood that various changes in form and details may be made therein without departing from the spirit and scope of the following claims.

1. A dicing film comprising:
a base layer;
an intermediate layer on the base layer; and
an adhesive layer on the intermediate layer,
wherein the adhesive layer includes an acrylate polymer composition including acrylonitrile.

2. The dicing film of claim 1, wherein an adhesive strength of the adhesive layer increases after an ultraviolet treatment is performed thereon, and the adhesive strength of the adhesive layer decreases after a heat treatment is performed thereon.

3. The dicing film of claim 2, wherein the adhesive layer undergoes a crosslinking reaction from Formula (1) below to Formula (2) below in the heat treatment:

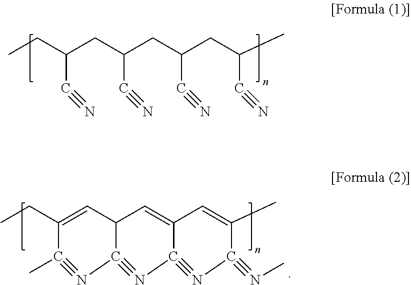

4. The dicing film of claim 3, wherein a temperature in the heat treatment is in the range of about 175° C. to about 250° C., and
the adhesive strength of the adhesive layer decreases according to Formula (2).

5. The dicing film of claim 2, wherein the adhesive strength of the adhesive layer after the ultraviolet treatment is greater than an initial adhesive strength of the adhesive layer, and
the adhesive strength of the adhesive layer after the heat treatment is less than the initial adhesive strength of the adhesive layer.

6. The dicing film of claim 1, wherein the adhesive layer includes acrylonitrile in a range of about 3 wt % to about 50 wt %.

7. The dicing film of claim 1, wherein a thickness of the adhesive layer is greater than a thickness of the base layer, and
the thickness of the base layer is greater than a thickness of the intermediate layer.

8. The dicing film of claim 7, wherein the adhesive layer comprises a single-layer high-temperature curable pressure sensitive adhesive, and
the thickness of the adhesive layer is within the range of about 30 μm to about 40 μm.

9. The dicing film of claim 8, wherein the adhesive layer further comprises a crosslinking agent and a photoinitiator.

10. The dicing film of claim 1, wherein the base layer includes a material selected from the group consisting of polyethylene terephthalate (PET), polyethylene naphthalate (PEN), polyether ether ketone (PEEK), and polyimide (PI), and
the intermediate layer includes ultraviolet curable synthetic resin or non-ultraviolet curable synthetic resin.

11. A pressure sensitive adhesive comprising
an acrylate polymer composition including acrylonitrile in a range of 3 wt % to 50 wt %,
wherein an adhesive strength of the pressure sensitive adhesive increases after an ultraviolet treatment is performed thereon, and
the adhesive strength of the pressure sensitive adhesive decreases after a heat treatment is performed thereon.

12. The pressure sensitive adhesive of claim 11, wherein the acrylonitrile forms ladder-polyacrylonitrile (ladder-PAN) from polyacrylonitrile (PAN) in the heat treatment at a temperature in the range of 175° C. to 250° C., and the adhesive strength of the pressure sensitive adhesive decreases due to high-temperature curing.

13. The pressure sensitive adhesive of claim 11, wherein the acrylate polymer composition includes at least one material selected from the group consisting of 2-ethylhexyl acrylate (EHA), 2-hydroxyethyl acrylate (HEA), and butyl acrylate (BA).

14. The pressure sensitive adhesive of claim 11, further comprising azobisisobutyronitrile (AIBN) as a photoinitiator.

15. The pressure sensitive adhesive of claim 14, wherein a polymerization reaction of the acrylate polymer composition includes a radical polymerization reaction using the photoinitiator.

16. A method of manufacturing a semiconductor package, the method comprising:
preparing a substrate structure with a first surface bonded on a carrier substrate;
bonding, to a dicing film, a second surface of the substrate structure opposite to the first surface;
separating the carrier substrate from the substrate structure and performing an ultraviolet treatment thereon;
bonding a solder ball to the first surface of the substrate structure and performing a heat treatment thereon;
separating the substrate structure into a plurality of semiconductor dies by cutting the substrate structure along a dicing line;
debonding and picking up the semiconductor dies from the dicing film; and
forming the semiconductor dies into semiconductor packages, respectively,
wherein the dicing film comprises:
a base layer;
an intermediate layer on the base layer; and
an adhesive layer on the intermediate layer, and
wherein the adhesive layer includes an acrylate polymer composition including acrylonitrile.

17. The method of claim 16, wherein an adhesive strength of the adhesive layer increases after the ultraviolet treatment, and
the adhesive strength of the adhesive layer decreases after the heat treatment.

18. The method of claim 17, wherein the adhesive strength of the adhesive layer after the ultraviolet treatment is greater than an initial adhesive strength of the adhesive layer, and
the adhesive strength of the adhesive layer after the heat treatment is less than the initial adhesive strength of the adhesive layer.

19. The method of claim 16, wherein the adhesive layer forms ladder-polyacrylonitrile (ladder-PAN) from polyacrylonitrile (PAN) at a certain temperature in the heat treatment, and the adhesive strength of the adhesive layer decreases.

20. The method of claim 19, wherein the certain temperature in the heat treatment is in the range of 175° C. to 250° C.

21-25. (canceled)
